(19) United States
(12) Patent Application Publication
(10) Pub. No.: US 2022/0384535 A1
(43) Pub. Date: Dec. 1, 2022

(54) DISPLAY PANEL, MANUFACTURE METHOD THEREFOR, AND DISPLAY DEVICE

(71) Applicant: BOE Technology Group Co., Ltd., Beijing (CN)

(72) Inventors: Xiaohu Li, Beijing (CN); Huajie Yan, Beijing (CN); Zhiqiang Jiao, Beijing (CN); Lu Wang, Beijing (CN)

(73) Assignee: BOE Technology Group Co., Ltd., Beijing (CN)

(21) Appl. No.: 17/773,314

(22) PCT Filed: Apr. 8, 2021
(86) PCT No.: PCT/CN2021/085921

§ 371 Date: Apr. 29, 2022

(30) Foreign Application Priority Data
May 9, 2020 (CN) 202010389903.9

(51) Int. Cl. H01L 27/32; H01L 51/56

(52) U.S. Cl. CPC H01L 27/3218; H01L 51/56; H01L 27/3248

(57) ABSTRACT

The present disclosure provides a display panel, a manufacture method therefor, and a display device. The display panel of the present disclosure has: a base substrate having a display area and a peripheral area surrounding the display area; first sub-pixels, second sub-pixels and third sub-pixels disposed in the display area; and a separating insulated layer disposed at a side of the base substrate, an orthographic projection of the separating insulated layer on the base substrate at least covering the display area; wherein the first sub-pixels are disposed at a side of the separating insulated layer away from the base substrate, and the second sub-pixels and the third sub-pixels are disposed between the separating insulated layer and the base substrate.

### CROSS REFERENCE TO RELATED APPLICATION(S)

The present disclosure is a National Stage Application of International Application No. PCT/CN2021/085921, which claims a priority of Chinese Patent Application No. 202010389903.9, filed on May 9, 2020, which is incorporated herein by reference in its entirety.

### TECHNICAL FIELD

The present disclosure relates to the technical field of display, and particularly to a display panel, a manufacture method therefor and a display device.

### BACKGROUND

In order to achieve full-color display, a process where a single color backlight device is used in combination with a color film to covert light with a single color to light with various colors, or a process where color light emitting devices are used to directly emit light with various colors can be adopted. For example, as for RGB color display, a white backlight device can be used to emit white light, and a RGB color film can be used to convert respective sub-pixels to RGB colors, or, RGB color light emitting devices can be directly used to form respective sub-pixels respectively which emit RGB light directly.

As compared to the process where color is converted by means of a color film, the process where color light emitting devices are used to directly emit light has advantages of wide color gamut range and small light intensity loss. However, this process has a disadvantage of low resolution.

There is still a need for improving high resolution display panel and display device.

### SUMMARY

In an aspect, the present disclosure provides a display panel comprising:

a base substrate comprising a display area and a peripheral area surrounding the display area:

first sub-pixels, second sub-pixels and third sub-pixels disposed in the display area; and

a separating insulated layer disposed at a side of the base substrate, an orthographic projection of the separating insulated layer on the base substrate at least covering the display area,

wherein the first sub-pixels are disposed at a side of the separating insulated layer away from the base substrate, and the second sub-pixels and the third sub-pixels are disposed between the separating insulated layer and the base substrate.

Preferably, the first sub-pixel comprises a first anode, a first light emitting layer and a first cathode stacked at the side of the separating insulated layer away from the base substrate.

Preferably, the second sub-pixel comprises a second anode, a second light emitting layer and a second cathode stacked between the base substrate and the separating insulated layer; and

the third sub-pixel comprises a third anode, a third light emitting layer and a third cathode stacked between the base substrate and the separating insulated layer.

Preferably, the second anode and the third anode are disposed in the same layer, and the second cathode and the third cathode are disposed in the same layer.

Preferably, the first sub-pixels are spaced apart from each other, and an orthographic projection of the first sub-pixel on the base substrate is between an orthographic projection of the second sub-pixel on the base substrate and an orthographic projection of the third sub-pixel on the base substrate.

Preferably, an orthographic projection of the first sub-pixel on the base substrate is at least partially overlapped with an orthographic projection of the second sub-pixel on the base substrate and/or an orthographic projection of the third sub-pixel on the base substrate.

Preferably, an orthographic projection of the second sub-pixel on the base substrate and an orthographic projection of the third sub-pixel on the base substrate are not overlapped with each other.

Preferably, the first sub-pixels are blue sub-pixels, the second sub-pixels are green sub-pixels, and the third sub-pixels are red sub-pixels.

Preferably, the display panel further comprises:

a buffer layer on the base substrate;

a thin film transistor layer at a side of the buffer layer away from the base substrate;

a passivation layer at a side of the thin film transistor layer away from the base substrate; and

a planarization layer at a side of the passivation layer away from the base substrate and between the base substrate and the second and third sub-pixels,

wherein the first sub-pixels, the second sub-pixels and the third sub-pixels are electrically connected to the thin film transistor layer via through holes penetrating the passivation layer and the planarization layer.

Preferably, the display panel further comprises an encapsulation layer at a side of the first sub-pixels away from the base substrate, wherein an orthographic projection of the encapsulation layer on the base substrate at least covers the display area.

In another aspect, the present disclosure provides a method for manufacturing a display panel, comprising:

providing a base substrate;

forming a second sub-pixel and a third sub-pixel at a side of the base substrate;

forming a separating insulated layer at a side of the second sub-pixel and the third sub-pixel away from the base substrate; and

forming a first sub-pixel at a side of the separating insulated layer away from the base substrate.

Preferably, the second sub-pixel and the third sub-pixel are formed by using a fine metal mask, and the first sub-pixel is formed by using an open mask.

In yet another aspect, the present disclosure provides a display device comprising the above-mentioned display panel.

### BRIEF DESCRIPTION OF THE DRAWINGS

FIG. 1 schematically shows an exemplary film layer structure of an embodiment of the present disclosure.

FIG. 2 schematically shows another embodiment of the present disclosure, where each pixel unit has four sub-pixels.

FIG. 3 schematically shows a partial schematic diagram of a pixel arrangement mode.

FIG. 4 schematically shows an exemplary film layer structure of another embodiment of the present disclosure.

FIG. 5 schematically shows an exemplary film layer structure of yet another embodiment of the present disclosure.

FIGS. 6(a)-(k) schematically show the manufacture steps of yet another embodiment of the present disclosure.

### DETAILED DESCRIPTION OF EMBODIMENTS

One structure of a color display panel without color film is formed by forming color sub-pixels on a substrate such as a TFT array substrate, where multiple color sub-pixels with different colors form a pixel or a pixel unit. For example, a pixel is composed of one R (red) sub-pixel, one G (green) sub-pixel and one B (blue) sub-pixel in parallel. The luminescence of the sub-pixels may be electroluminescence. That is, the luminescence is achieved by applying a voltage to a light emitting layer between an anode and a cathode through the anode and cathode. Organic light emitting diode (OLED) is a representative for electroluminescence. In the present disclosure. OLED is used as an example for description hereinafter. Nevertheless, the display panel of the present disclosure is not limited to an OLED display panel, and may be, for example, an all-inorganic quantum dot display panel.

Because the film layer structures of the sub-pixels in the direction perpendicular to the array substrate are substantially the same, except that the materials for the light emitting layers are different, typically, film layers other than the light emitting layers in the sub-pixels including, but not limited to, electron injection layers, electron transport layers, hole injection layers, hole transport layers, electron blocking layers, hole blocking layers, or the like, are all formed in the same layer in the sub-pixels with various colors of the entire display panel. For example, because the R. G and B sub-pixels all need an electron injection layer to be provided, a material for the electron injection layer is applied or deposited in the entire effective display area to form the electron injection layers of the R, G and B sub-pixels at the same time. In the sub-pixels with different colors, only the light emitting layers need to be formed separately because of different materials. The electrodes of each sub-pixel may be formed from the same material and spaced apart from each other to achieve individual luminescence of each sub-pixel.

A simple process for forming a film layer other than the light emitting layer is to make a film layer continuously cover a plurality of sub-pixel regions with different colors. In other words, the electron injection layers of the R, G and B sub-pixels may be the same continuous layer. In other words, the R, G and B sub-pixels may have a common electron injection layer. However, when the carrier migration rate inside such a common film layer is high and the sub-pixels are closely adjacent to each other, the carriers may migrate from one sub-pixel region to an adjacent sub-pixel region with another color along the common film layer and cause luminescence, thereby resulting in the problem of pixel interference and thus influencing the display effect.

It may be contemplated to avoid the interference by providing a sub-pixel defining layer perpendicular to the substrate extending direction between adjacent sub-pixels with different colors to discontinue the above common film layer to prevent the lateral transfer of the carriers between the sub-pixels. However, in this manner, the distance between the sub-pixels is increased, reducing the resolution of the display panel, while the complexity of the process is greatly increased due to the presence of the sub-pixel defining layer and the regional deposition of various film layers.

Also, it may be contemplated to reduce the interference by increasing the distance between the sub-pixels to make the lateral transfer of the carriers in the common film layer difficult, thereby reducing the lateral transfer of electrons between pixels. In this manner, the resolution of the display panel will be reduced.

Furthermore, when depositing adjacent light emitting layers with different colors, because they are disposed at the same level in a direction perpendicular to the array substrate, the blending of materials for the light emitting layers easily occurs, resulting in color mixing. In this regard, it is necessary to use a fine metal mask (FMM) to form each light emitting layer. When color sub-pixels with different colors are disposed closely adjacent to each other in parallel, the resolution of the display panel is limited because of the limitations of the opening accuracy and the alignment accuracy of the FMM.

The present disclosure proposes a display panel having a sub-pixel spatial arrangement in a direction perpendicular to the base substrate, which may at least partially solve the above problems.

In an embodiment, the present disclosure provides a display panel comprising:

a base substrate comprising a display area and a peripheral area surrounding the display area;

first sub-pixels, second sub-pixels and third sub-pixels disposed in the display area: and

a separating insulated layer disposed at a side of the base substrate, an orthographic projection of the separating insulated layer on the base substrate at least covering the display area,

wherein the first sub-pixels are disposed at a side of the separating insulated layer away from the base substrate, and the second sub-pixels and the third sub-pixels are disposed between the separating insulated layer and the base substrate.

In other words, the first sub-pixels and the second and third sub-pixels in the display panel of the present disclosure are disposed on different sides of a separating insulated layer respectively. The first sub-pixels are insulated from the second sub-pixels, and insulated from the third sub-pixels as well. With respect to the separating insulated layer, the first sub-pixels are away from the base substrate of the display panel, while the second and third sub-pixels are close to the base substrate, or in other words, disposed between the separating insulated layer and the base substrate.

As such, by maintaining the first sub-pixels insulated from the second and third sub-pixels, any interference between the first sub-pixels and the second and third sub-pixels caused by the carrier migration may be prevented.

The base substrate may be any base substrate suitable for a display panel, such as a rigid base substrate or a flexible base substrate. Specifically, it may be a glass substrate, an organic resin substrate or the like.

It is proposed in the present disclosure to avoid the interference between the sub-pixels due to the common functional layer as mentioned above by providing a separating insulated layer to spatially design the sub-pixel structure in a direction perpendicular to the base substrate. This can in turn make the sub-pixels arranged closely adjacent to each other and omit the sub-pixel defining layer, achieving a high resolution display panel. It should be appreciated that the wordings “first”, “second” and “third” referring to the sub-pixel are only intended to distinguish their different positions.

The separating insulated layer is disposed at the same side of the base substrate as the first, second and third sub-pixels. An orthographic projection of the separating insulated layer on the base substrate at least covers the display area, In an embodiment, the orthographic projection of the separating insulated layer on the base substrate covers the boundary between the orthographic projections of the first sub-pixels and the second sub-pixels, and the boundary between the orthographic projections of the first sub-pixels and the third sub-pixels. In an embodiment, the orthographic projection of the separating insulated layer on the base substrate covers the orthographic projections of the first sub-pixels, the second sub-pixels and the third sub-pixels on the base substrate. The separating insulated layer may extend throughout the entire pixel unit in a direction parallel to the base substrate to ensure insulation and separation. In an embodiment, the separating insulated layer may extend in a plurality of pixel units of the entire effect display area in a direction parallel to the base substrate, or even extend throughout the entire display panel. In an embodiment, the separating insulated layer extends in a plane of each sub-pixel parallel to the base substrate, and is continuous between adjacent sub-pixels. The separating insulated layer may substantially cover the entire display area except the bottoms of the through holes in the first sub-pixels. The separating insulated layer may be a continuous planar layer parallel to the base substrate, or a continuous but non-planar layer. The material useful for the separating insulated layer should be insulating, have a good binding property with other film layers, and be formed into a film easily. The examples thereof may comprise silicon oxide, silicon nitride and the like.

FIG. 1 shows an exemplary film layer structure of an embodiment comprising a TFT array substrate of the present disclosure. Here, the display panel comprises:

a base substrate S comprising a display area and a peripheral area surrounding the display area, with only one pixel in the display area shown in the figure:

one first sub-pixel a, one second sub-pixel b and one third sub-pixel c disposed in the display area; and

a separating insulated layer 204 disposed at a side of the base substrate S, an orthographic projection of the separating insulated layer 204 on the base substrate S at least covering the display area.

The first sub-pixel a is disposed at a side of the separating insulated layer away from the base substrate S. The second sub-pixel b and the third sub-pixel c are disposed between the separating insulated layer 204 and the base substrate S.

The present invention is particularly suitable for an electroluminescent display panel. The basis configuration of an electroluminescent sub-pixel comprises an anode, a cathode and a light emitting layer between the anode and the cathode. In an embodiment, the first sub-pixel comprises a first anode, a first light emitting layer and a first cathode stacked at the side of the separating insulated layer away from the base substrate. In an embodiment, the second sub-pixel comprises a second anode, a second light emitting layer and a second cathode stacked between the base substrate and the separating insulated layer. The third sub-pixel comprises a third anode, a third light emitting layer and a third cathode stacked between the base substrate and the separating insulated layer. The first anode is disposed at a side of the separating insulated layer away from the base substrate, such that the entire first sub-pixel is located at the side of the separating insulated layer away from base substrate. Meanwhile, the second cathode and the third cathode are disposed between the separating insulated layer and the base substrate, such that the second sub-pixel and the third sub-pixel are both disposed between the separating insulated layer and the base substrate.

As shown in FIG. 1, the first sub-pixel a comprises a first anode a201, a first light emitting layer a202 and a first cathode a203 stacked one on top of another at a side of the separating insulated layer 204 away from the base substrate S. The second sub-pixel b comprises a second anode b201, a second light emitting layer b202 and a second cathode b203 stacked one on top of another between the base substrate S and the separating insulated layer 204. The third sub-pixel comprises a third anode c201, a third light emitting layer c202 and a third cathode c203 stacked one on top of another between the base substrate S and the separating insulated layer 204. In all the drawings of the present disclosure, the size and scale, such as the size and scale of a step or a height difference are only schematic.

In an embodiment, the second anode and the third anode are disposed in the same layer. The second cathode and the third cathode are disposed in the same layer. Generally, the materials for the cathodes of the second and third sub-pixels may be the same, and the materials for the anodes may also be the same. Here, the anodes or cathodes of the second and third sub-pixels may be formed in the same process at the same time. For example, an anode material layer may be deposited in the display area, and the anode material layer may be patterned into the second anode and the third anode by a patterning process. In the present disclosure, the phrase “being disposed in the same layer” or “being formed in the same layer” means that components in different regions are formed from the same material by the same process.

As shown in FIG. 1, the second anode b201 and the third anode c201 are disposed in the same layer. The second cathode b203 and the third cathode c203 are disposed in the same layer.

In an embodiment, each pixel unit may be composed of one first sub-pixel, one second sub-pixel and one third sub-pixel. As described below, the pixel unit may also comprise more sub-pixels.

In an embodiment, an orthographic projection of the first sub-pixel on the base substrate is between orthographic projections of the second sub-pixel and the third sub-pixel on the base substrate. As shown in FIG. 1, the orthographic projection of the first sub-pixel a on the base substrate S is between the orthographic projections of the second sub-pixel b and the third sub-pixel c on the base substrate S.

The light emitting layer of the fast sub-pixel is disposed at the side of the separating insulated layer away from base substrate. The light emitting layer of the second sub-pixel and the light emitting layer of the third sub-pixel are disposed at a side of the separating insulated layer close to the base substrate, and between the separating insulated layer and the base substrate. There is no carrier migration path between the light emitting layer of the first sub-pixel and the light emitting layers of the second and third sub-pixels. In this manner, the first sub-pixel and the second sub-pixel are disposed on different sides of the separating insulated layer, and the first sub-pixel and the third sub-pixel are disposed on different sides of the separating insulated layer as well. Also, when the orthographic projection of the first sub-pixel on the base substrate is disposed between the orthographic projections of the second sub-pixel and the third sub-pixel on the base substrate, the second and third sub-pixels in the same pixel unit are separated away from each other. As such, in one pixel unit, the lateral carrier migration between the second and third sub-pixels due to sharing a functional layer may be omitted, thereby avoiding the interference. Thus, no interference with each other will occur among the three sub-pixels in one pixel unit.

Specifically, when the first sub-pixel emits light, the carriers thereof all migrate at the side of the separating insulated layer away from the base substrate, such that the second and third light emitting layers at the side of the separating insulated layer close to the base substrate will not emit light. When the second or third sub-pixel emits light, the carriers thereof all migrate at the side of the separating insulated layer close to the base substrate, such that the first light emitting layer at the side of the separating insulated layer away from the base substrate will not emit light. Also, in a direction parallel to the base substrate, the second and third light emitting layers are separated by the first sub-pixel. The distance is large enough, such that there are few carriers laterally migrated between the second and third sub-pixels, thus avoiding the interference therebetween.

In an embodiment, first sub-pixels are spaced apart from each other, and the orthographic projection of the first sub-pixel on the base substrate is disposed between the orthographic projections of the second sub-pixel and third sub-pixel on the base substrate. That is, one first sub-pixels and another first sub-pixel are not disposed adjacent to each other, but are separated by the second or third sub-pixel. For example, in a direction, the sub-pixels may be arranged repeatedly in an order of the first sub-pixel, the second sub-pixel, the first sub-pixel and the third sub-pixel.

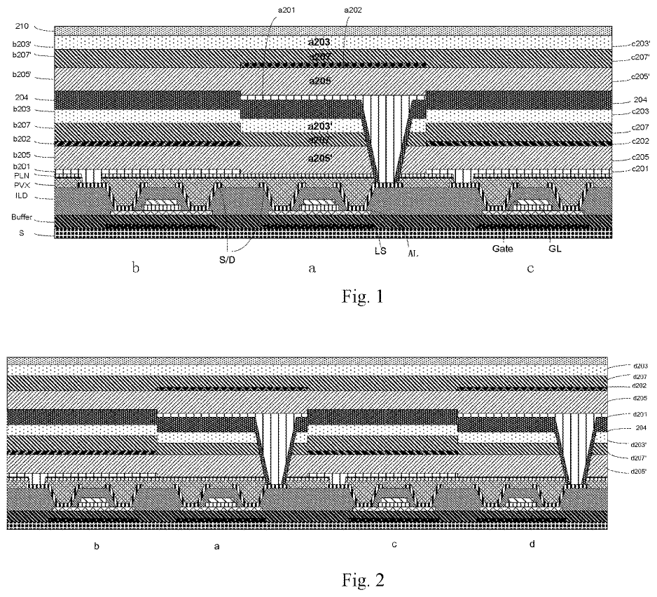

FIG. 2 shows a schematic diagram of an embodiment where the sub-pixels are arranged repeatedly in the above manner. Here, each pixel unit has four sub-pixels. In FIG. 2, the rightmost sub-pixel is also a blue sub-pixel, which has the same structure as the sub-pixel a, which means that it is also a first sub-pixel. The embodiment with four sub-pixels may enhance blue light emitting. Furthermore, such a pixel unit is also convenient for continuous arrangement of adjacent pixel units, and may be suitable for the following pixel arrangement, for example.

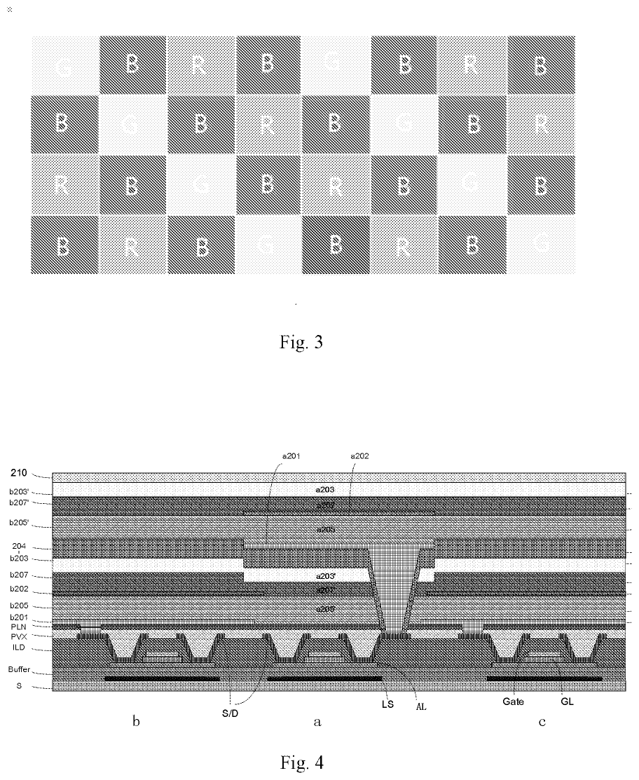

FIG. 3 shows a schematic diagram of an embodiment where the sub-pixels are arranged in the above manner in a plane. This figure shows the projections of the sub-pixels on the base substrate plane. Here, the blue sub-pixel B is a first sub-pixel, the green sub-pixel G is a second sub-pixel, the red sub-pixel R is a third sub-pixel, and they are arranged repeatedly in the manner as shown in FIG. 2 in both lateral and longitudinal directions. Specifically, the first row comprises two GBRB pixel units with four sub-pixels as shown in FIG. 2. In the second to the fourth rows, the pixel units sequentially translate rightwards by a distance of one sub-pixel. This may result in that in any two adjacent sub-pixels, one comprises a sub-pixel at the side of the separating insulated layer away from the base substrate, while the other one comprises a sub-pixel between the separating insulated layer and the base substrate. As such, the interference between adjacent sub-pixels due to a common film layer is avoided. In view of the orthographic projections on the base substrate, the first sub-pixels, the second sub-pixels and the third sub-pixels are collectively arranged into a rectangular array, and in the row and column direction of the rectangular array, the second sub-pixel is on one end of each first sub-pixel, while the third sub-pixel is on the other end; the first sub-pixels are on both ends of each second sub-pixel; and the first sub-pixels are on both ends of each third sub-pixel as well. Such an arrangement is beneficial for obtaining higher resolution and better display effect, and reducing the difficulty and cost of the process. The arrangement of sub-pixels in a plane in the present disclosure is not limited to the manner as shown in FIG. 3, and may be appropriately designed according to particular requirements.

In an embodiment, the orthographic projection of the first sub-pixel on the base substrate is at least partially overlapped with the orthographic projection of the second sub-pixel and/or the third sub-pixel on the base substrate. That is, the orthographic projection of the first sub-pixel on the base substrate may be at least partially overlapped with the orthographic projection of the second sub-pixel on the base substrate, but not at least partially overlapped with the orthographic projection of the third sub-pixel on the base substrate. The orthographic projection of the first sub-pixel on the base substrate may be at least partially overlapped with the orthographic projection of the third sub-pixel on the base substrate, but not at least partially overlapped with the orthographic projection of the second sub-pixel on the base substrate. The orthographic projection of the first sub-pixel on the base substrate may be at least partially overlapped with the orthographic projections of the second and third sub-pixel on the base substrate. In the present disclosure, because the first sub-pixel is disposed at a different level from the second and third sub-pixels, the orthographic projections of them may be at least partially overlapped with each other. In a region where an orthographic projection of the anode of the first sub-pixel is overlapped with the second and third sub-pixels, the first sub-pixel may block the light emitted by the second and third sub-pixels, such that the display effect will not be influenced.

When the anode of the first sub-pixel is opaque, the anode may block any light output from the separating insulated layer to the side of away from the base substrate. Thus, the second and third sub-pixels on both sides thereof may extend into the region of the first pixel. As such, with the same resolution, the light emitting layers and/or anodes of the second and third sub-pixels in the pixel unit of the present disclosure may have a relatively large area, such that the accuracy requirement for the manufacture process may be significantly reduced, thereby reducing the cost and increasing the yield. In particular, in the case of high resolution, in order to achieve the deposition of a small area of light emitting layer material in each sub-pixel, a FMM with an equally small opening is needed. In the embodiments of the present disclosure, a FMM with a relatively large opening may be used to deposit the light emitting layer material with a relatively large area, but the same resolution may still be obtained.

FIG. 4 shows a schematic diagram of an embodiment where the orthographic projection of the first sub-pixel on the base substrate is at least partially overlapped with the orthographic projections of the second sub-pixel and the third sub-pixel on the base substrate. Here, the projections of the right end of the second sub-pixel b and the left end of the third sub-pixel on the base substrate are both overlapped with the projection of the first sub-pixel a.

The anode a201 of the first sub-pixel is opaque. The orthographic projections of the second light emitting layer b202 and the third light emitting layer c202 on the base substrate are overlapped with the orthographic projection of the anode a201 on the base substrate. That is, the second anode b201, the second light emitting layer b202, the third anode c201, and the third light emitting layer c202 all extend below the anode a201 of the first sub-pixel, i.e., into a region between it and the base substrate. Here, although the second light emitting layer b202 and the third light emitting layer c202 in these overlapped regions emit light, the emitted light will not transmit though the opaque first anode a201, and thus the display will not be influenced. Because relatively large second light emitting layer, third light emitting layer, second anode and third anode may be formed, a FMM with a relatively large opening may be used, and the resolution will not be thereby reduced.

In FIG. 4, the anode b201 of the second sub-pixel extends less into the first sub-pixel a than its light emitting layer b202, while the anode c201 of the third sub-pixel extends further into the first sub-pixel than its light emitting layer c202. This is only schematic, indicating that the particular situations of the second and third sub-pixels below the first sub-pixel may be not particularly limited in the present disclosure. Furthermore, the height difference due to the above extending of the second or third anode or light emitting layer may be smoothed or planarized by using a suitable film layer in the first sub-pixel.

In an embodiment, the orthographic projection of the second sub-pixel on the base substrate is not overlapped with the orthographic projection of the third sub-pixel on the base substrate. That is, the second sub-pixel and the third sub-pixel are arranged in parallel and have no overlapped portion with each other. The second sub-pixel and the third sub-pixel may be adjacent to each other, but not overlapped with each other. For example, although the green sub-pixel G and the red sub-pixel R are adjacent to each other at four corners of the sub-pixels, as shown in FIG. 3, they are not overlapped with each other.

In an embodiment, the vertical distance from the second sub-pixel to the base substrate equals to the vertical distance from the third sub-pixel to the base substrate. In other words, the same kind of film layers of the second sub-pixel and the third sub-pixel may be formed in the same layer. That is, the anodes, the cathodes, and other functional layers such as the hole injection layers, the hole transport layers, the electron transport layers, and the electron injection layers of the second sub-pixel and the third sub-pixel may all be formed in the same layer respectively.

In the present disclosure, the term “common layer” means that this layer is shared by the sub-pixels in a pixel unit, and has the same material and relative position. In other words, each sub-pixel has a film layer containing the material of this common layer, and with reference to other common film layers, die film layer of this material is disposed in the same relative position, but this film layer may have different functions in the respective sub-pixels. In some embodiments, the common layer in adjacent sub-pixels may also be discontinuous. Nevertheless, the separating insulated layer is continuous in adjacent sub-pixels.

In an embodiment, the first sub-pixel is a blue sub-pixel, the second sub-pixel is a green sub-pixel, and the third sub-pixel is a red sub-pixel. Currently, as compared to red and green organic light emitting materials, blue organic light emitting material has relatively poor light emitting property. Therefore, a better display effect may be obtained by disposing the blue sub-pixel in the center of the pixel and closer to the light-exiting surface (i.e. away from the base substrate). It should be noted that because both the second sub-pixel and the third sub-pixel are disposed between the separating insulated layer and the base substrate, they may be exchanged with each other in view of the position relationship between them and the separating insulated layer. Therefore, it may also be said that the second sub-pixel is a red sub-pixel, and the third sub-pixel is a green sub-pixel.

The display panel of the present disclosure may comprise a thin film transistor (TFT) array substrate. The TFT array substrate may be any TFT array in related art, as long as it is in line with the principle of the present disclosure. Typically, a TFT comprises source/drain electrodes (S/D), an active layer (AL), a gate insulation layer (GI) and a gate electrode (Gate), and may further comprise, for example, an interlayer dielectric layer (IDL). The TFT used is not particularly limited in the present disclosure. The TFT array substrate may also comprise usual film layers such as a base substrate (S), a buffer layer (Buffer), a light shielding layer (LS), a passivation layer (PVX), and a planarization layer (PLN) in related art.

In an embodiment, the display panel further comprises:

a buffer layer on the base substrate;

a thin film transistor layer at a side of the buffer layer away from the base substrate;

a passivation layer at a side of the thin film transistor layer away from the base substrate; and

a planarization layer at a side of the passivation layer away from the base substrate and between the base substrate and the second and third sub-pixels,

wherein the first sub-pixels, the second sub-pixels and the third sub-pixels are electrically connected to the thin film transistor layer via through holes penetrating the passivation layer and the planarization layer.

The light emitting device of the sub-pixel may be any type in related art, as long as it is in line with the principle of the present disclosure. An OLED sub-pixel is preferred.

As shown in FIG. 1, the display panel may further comprise a buffer layer (Buffer), a thin film transistor layer, a passivation layer (PVX), and a planarization layer (PLN). The thin film transistor layer may comprise source/drain electrodes (S/D), an active layer (AL), a gate insulation layer (GI), a gate electrode (Gate), and an interlayer dielectric layer (IDL). The display panel may further comprise other film layers such as a light shielding layer (LS).

The first, second and third sub-pixels are all electrically connected to the thin film transistor layer via through holes penetrating the passivation layer and the planarization layer. The through hole of the first sub-pixel also penetrates the separating insulated layer 204, and the film layers between the planarization layer (PLN) and the separating insulated layer 204. The first anode a201 is in electrical communication with the source/drain electrodes (S/D) via this through hole.

The present disclosure relates to high resolution display device, and a top-emitting configuration, i.e., a configuration where the light-exiting surface is at a side away from the base substrate, is preferred. Typically, the display device comprises an anode at a side close to the base substrate (i.e., a bottom electrode), a cathode at a side away from the base substrate (i.e., a top electrode) and a light emitting layer therebetween, wherein the cathode is transparent or translucent such that the light generated may transmit through the cathode, and the anode may be a reflecting electrode for reflecting the light generated. In an embodiment, the proximal electrode is a reflecting anode, and the distal electrode is a transparent cathode. In the present disclosure, the terms “proximal” and “distal” refer to the distance from the base substrate. In addition to the light emitting layer and the electrodes, the display device may further comprise any functional film layer in related art, as long as it is in line with the principle of the present disclosure. The functional film layer includes, but not limited to, an electron/hole injection layer/transport layer/blocking layer, an encapsulation layer, and the like. Particular film layer structure may be appropriately selected without departing from the spirit of the present disclosure.

In an embodiment, the display panel further comprises an encapsulation layer at a side of the first sub-pixels away from the base substrate, wherein an orthographic projection of the encapsulation layer on the base substrate at least covers the display area. The encapsulation layer completely encapsulates the spatially arranged first, second and third sub-pixels. The encapsulation layer may be inorganic or organic, or may comprise a film layer having a plurality of inorganic layers and organic layers stacked. As shown in FIG. 1, the encapsulation layer 210 is at a side of the first sub-pixel a away from the base substrate, and an orthographic projection thereof at least covers the display area.

In the display panel of the present disclosure, it is not necessary to provide a sub-pixel defining layer between adjacent sub-pixels in the same pixel unit, and in view of the orthographic projection on the base substrate, the sub-pixels may be disposed closely adjacent to each other without any interference occurred, so that a high resolution may be achieved. In other words, the present disclosure solves the problem of interference due to the common film layer between adjacent sub-pixels in the same pixel unit. In the present disclosure, in the case where adjacent sub-pixels of two adjacent pixel units are disposed in parallel, interference may be prevented by keeping a distance or providing a separator therebetween. For example, when each pixel unit is composed of the second sub-pixel, the first sub-pixel and the third sub-pixel in this order as shown in FIG. 1, the third sub-pixel of one pixel unit may be disposed in parallel to the second sub-pixel of the next pixel unit. Here, a distance between the two pixel units may be set such that the interference between the third sub-pixel and the second sub-pixel is small enough. For display devices with different size scales, the distances between pixel units may be different. For example, for a television screen, the distance between pixel units may be set to be tens of microns. For a conventional small screen, the distance between pixel units may be set to be several microns to tens of microns. For a Micro-OLED, the distance between pixel units may be on the order of sub-micron. Furthermore, the influence of interference between the two pixel units on display may be prevented by providing a pixel defining layer between the two pixel units. Preferably, by using, for example, the arrangement design as shown in FIG. 3, it is not necessary to provide the above distance between pixel units and pixel defining layer in the embodiment of the present disclosure, thereby further improving the resolution.

The space at a side of the separating insulated layer away from the base substrate at the positions of the second and third sub-pixels and the space at a side of the separating insulated layer close to base substrate at the position of the first sub-pixel need to be filled. A filling material may be specially provided in these spaces. Nevertheless, in view of the process, it is more advantageous to use the common layer formed in the same layer to fill these spaces.

In an embodiment, the film layer in a sub-pixel region is extended into an adjacent sub-pixel region to fill the space in the adjacent sub-pixel region. For example, when forming the cathode layer of the first sub-pixel, the cathode layer is also formed in the same layer in the regions of the second sub-pixel and the third sub-pixel. Such cathode layer formed in the same layer in the regions of the second sub-pixel and the third sub-pixel is at a side of the separating insulated layer away from the base substrate, and thus will not participate in the luminescence of the second and third sub-pixels, but only functions to fill the space.

Such film layer formed in the same layer includes an electron/hole injection layer/transport layer/blocking layer, a cathode layer and the like. The above other film layers may be formed by entire surface deposition, coating, or the like. By using such a design of common film layer, the continuous structure of material between sub-pixels may be maintained, while the interference problem due to lateral carrier migration will not occur because of the spatial design of the present disclosure. The common film layer acts as a functional film layer in some sub-pixels, and functions to fill the space in some other sub-pixels. The common film layer fills the portion which does not need a functional layer in the sub-pixel spatial design, and may be made by a simple fabrication process.

One particular embodiment may be as shown in FIG. 1.

The leftmost second sub-pixel b comprises an anode b201 electrically connected to the drain electrode. The anode b201 is used for hole injection. Therefore, a hole injection layer and a hole transport layer (HIL/HTL) are formed thereon sequentially. For simplification, both of them are collectively designated by b205 in FIG. 1. Then, a green light emitting layer (G EML, designated by b202), an electron transport layer and an electron injection layer (ETL/EIL, collectively designated by b207), and a cathode b203 are formed. These components may be the same as conventional film layer structures in the art, and form a green sub-pixel capable of emitting light. At a side of the second sub-pixel region away from the base substrate, there are a separating insulated layer 204, HIL/HTL (b205′), ETL/EIL (b207′), an electrode layer b203′ and an encapsulation layer 210 in sequence.

The rightmost third sub-pixel c has a similar structure to the second sub-pixel b, and the difference therebetween is that the light emitting layer is a red light emitting layer (R EML, designated by c202). The anode c201 is electrically connected to the drain electrode. The anode c201 is used for hole injection. Therefore, a hole injection layer and a hole transport layer (HIL/HTL) are formed thereon sequentially. For simplification, both of them are collectively designated by c205 in FIG. 1. Then, a red light emitting layer (R EML, designated by c202), an electron transport layer and an electron injection layer (ETL/EIL, collectively designated by c207), and a cathode c203 are formed. These components may be the same as conventional film layer structures in the art, and form a red sub-pixel capable of emitting light. At a side of the third sub-pixel region away from the base substrate, there are a separating insulated layer 204, HIL/HTL (c205′), ETL/EIL (c207′), an electrode layer c203′ and an encapsulation layer 210 in sequence.

The anode a201, HIL/HTL a205, blue light emitting layer (B EML, a202), ETL/EIL (a207), and cathode a203 of the middle first sub-pixel b are all disposed at a side of the separating insulated layer 204 away from the base substrate. Between the separating insulated layer and the base substrate in the first sub-pixel region, there are HIL/HTL (a205′), ETL/EIL (a207′) and an electrode layer a203′ in sequence.

In the figure, for simplification and clarity, all the hole/electron transport/injection layers and the anodes on both sides of the separating insulated layer 204 are designated by the same reference numbers. It may be appreciated that they may be different from each other. For example, a material different from that of the blue hole injection/transport layers a205 may be selected as the material for the red hole injection/transport layers b205.

As seen from the figure, the functional film layers such as HIL/HTL a205 participating in luminescence in the first sub-pixel are formed in a different layer from the functional film layers b205, c205 participating in luminescence in the second and third sub-pixels, but is formed in the same layer as the film layers b205′, c205′ in the second and third sub-pixel regions. Likewise, the film layers b205, c205 participating in luminescence in the second and third sub-pixels are formed in the same layer as the film layers a205′ in the first sub-pixel region. Likewise, the film layers b207, c207 are formed in the same layer as the film layers a207′, and the film layers b207′, c207′ are formed in the same layer as the film layers a207. Therefore, interference due to lateral carrier migration between film layers participating in luminescence of the sub-pixels will not occur.

FIG. 1 shows that the electrical connection between the first anode and the TFT is achieved via a through hole, which has an inverse conical shape and the inner wall of which is covered by the material for the separating insulated layer.

FIG. 1 shows that orthographic projections of proximal electrodes of the three sub-pixels on the base substrate may be arranged completely closely adjacent to each other. In contrast, if the spatial design of the present disclosure is not used, in an embodiment of related art where three proximal electrodes are disposed in the same layer, a sufficient gap must be remained or a pixel defining layer must be provided between the proximal electrodes of adjacent sub-pixels. Otherwise, short circuit between the sub-pixels may occur.

In the present disclosure, the aforementioned spatial design may also be achieved without any common film layer. For example, a single transparent material may be uniformly filled at a side of the separating insulated layer without the light emitting layer in the sub-pixel. Nevertheless, in view of simplicity of the process, the aforementioned embodiment with common film layers provided is preferred.

In an embodiment where the first sub-pixel, the second sub-pixel and the third sub-pixel are respectively a blue pixel unit, a green pixel unit and a red pixel unit, standard RGB sub-pixels are provided. As described above, because the blue sub-pixel has a relatively poor light emitting property, it is preferably disposed closer to the light-exiting surface. Furthermore, usual hole injection layer/transport layer have good transmittance for red/green light, ensuring that the light emitting property thereof will not be significantly influenced when red and green sub-pixels are disposed on both flanks.

In an embodiment, each pixel unit is composed of four sub-pixels, including two first sub-pixels, one second sub-pixel and one third sub-pixel. For example, the four sub-pixels may be arranged in one row, forming an arrangement of second sub-pixel-first sub-pixel-third sub-pixel-first sub-pixel or an equivalent thereof, as shown in FIG. 2.

Here, the second or third sub-pixel is at a different side of the separating insulated layer from the two first sub-pixels on both ends. The pixel unit comprising the above four sub-pixels may contribute to improving the display quality. The RBGB type pixel unit is an example of a pixel unit comprising four sub-pixels. Because the property such as luminance of a blue organic light emitting material is poorer than a red/green organic light emitting material, the blue light emitting property of the display panel may be improved by providing one more blue pixel in the pixel unit.

Another advantage of such a four sub-pixel arrangement is that the light emitting layers of the last sub-pixel of a pixel unit and the first sub-pixel of the next pixel unit are respectively disposed at two sides of the separating insulated layer. Therefore, adjacent pixel units may be closely adjacent to each other without any interference occurred, it is not necessary to maintain a large distance between the pixel units, and it is not necessary to provide a pixel defining layer, either. This is convenient for continuously arranging adjacent pixel units, thereby further improving the resolution of the display panel.

For example, when each pixel unit comprises four sub-pixels, the pixel units may be appropriately arranged, such that in view of the orthographic projection on the base substrate, the first sub-pixels, the second sub-pixel and the third sub-pixel are collectively arranged into a rectangular array, and in the row and column direction of the rectangular array, the first sub-pixels are adjacent to both ends of the second sub-pixel, and the first sub-pixels are adjacent to both ends of the third sub-pixel as well; the second sub-pixel and the third sub-pixel are respectively adjacent to two ends of the first sub-pixels. In other words, in the display panel, each sub-pixel is adjacent to four sub-pixels, and the light emitting layer in each sub-pixel and the light emitting layer of the adjacent sub-pixel are respectively disposed on different sides of the separating insulated layer. As such, the problem of interference between any adjacent sub-pixels due to lateral carrier migration in the common film layer may be avoided by the spatial design. One particular embodiment may be as shown in FIG. 3. Here, blue is distal, and one pixel unit is provided with four sub-pixels, including two blue sub-pixels. By staggered arrangement of such pixel units, the disadvantage of poor light emitting property of a blue light emitting layer may be remedied sufficiently, while no interference will occur between adjacent pixel units. Of course, other manners of arrangement may also be appropriately designed, and the appearance of the sub-pixel may also be appropriately selected, and does not have to be the rectangular array and rectangular sub-pixel as shown in FIG. 3.

One pixel unit may also comprise more sub-pixels, such as five, six, seven and eight sub-pixels, as long as the sub-pixels are arranged by disposing the first sub-pixel and the second or third sub-pixel in a staggered manner.

In the present disclosure, when there is an array substrate, the anodes of the second and third sub-pixels are similar to those in related art, and may be directly disposed on the surface of the array substrate and may be easily electrically connected to the TFT therein. For example, their anodes may be connected to the TFT via through holes penetrating the planarization layer and the passivation layer. However, the anode of the first sub-pixel is at a side of the separating insulated layer away from the array substrate, and thus cannot be directly formed on the TFT array substrate. In an embodiment, the first sub-pixel is electrically connected to the TFT via a through hole, wherein the through hole penetrates the separating insulated layer and the film layers at a side of the separating insulated layer close to the array substrate at the position of the first sub-pixel, and has an insulating inner wall. The inner wall of the through hole (in the present disclosure, sometimes referred to as a first sub-pixel through hole) is insulating, thereby completely preventing the current in the first sub-pixel from influencing the second and third sub-pixels on both flanks thereof.

In an embodiment, the inner wall of the first sub-pixel through hole has the same material as the separating insulated layer. As such, in fabrication, the through hole having an insulating inner wall may be formed while forming the separating insulated layer, thereby simplifying the manufacture method. For example, the separating insulated layer may be formed at the position of the first sub-pixel on a common cathode, which is also possessed by the second cathode and the third cathode. In this case, before forming the separating insulated layer, the first sub-pixel through hole is firstly formed, wherein the through hole extends from the cathode to the source/drain electrodes of the TFT, and penetrates all the film layers therebetween. Then, the separating insulated layer is formed to cover the cathode and also cover the inner wall of the first sub-pixel through hole. Nevertheless, at the bottom of the first sub-pixel through hole, the separating insulated layer is not covered, that is, the source/drain electrodes of the TFT are exposed. The exposure of the source/drain electrodes may be achieved by depositing the separating insulated layer with a mask, wherein the mask is used to block the source/drain electrodes. As such, the through hole having an insulating inner wall is formed while forming the separating insulated layer. Thereafter, a conductive material such as the material for the first anode may be filled in the through hole, and then the first anode is formed on the separating insulated layer, so as to achieve the electrical connection between the first anode and the TFT. The path of the electrical connection is insulated from the film layers around the through hole, and thus is insulated from the second and third sub-pixels.

In order to facilitate the formation of the insulating surface of the inner wall by deposition, the through hole is preferably an inverse conical hole.

In an embodiment, there is no pixel defining layer between adjacent pixel units, thereby simplifying the process and improving the resolution. The pixel defining layer may be omitted by maintaining the distance between the pixel units. The lateral carrier migration may also be avoided spatially by, for example, the above design with four sub-pixels, thereby omitting the pixel defining layer.

In an embodiment, the display panel of the present disclosure may have a resolution up to 1000 ppi or more, or even up to 3000 ppi or more.

In an embodiment, the first light emitting layer extends out of the first sub-pixel, and the orthographic projection of the first light emitting layer on the base substrate is overlapped with the orthographic projection of the second sub-pixel and/or the third sub-pixel on the base substrate. Typically, the light emitting area of a sub-pixel is essentially defined by the smaller one in the anode and the light emitting layer, because the cathode is usually a common electrode and has an area generally larger than that of the anode and that of the light emitting layer. The first light emitting layer may be disposed only within the interior the first sub-pixel, or may extend out of the first sub-pixel, or even may extend throughout the entire effective display area. Because the first light emitting layer (for example, the blue light emitting layer) in the middle may have no blocking effect on the light emitted by the second and third light emitting layers (red light and green light), it will not influence the display effect even if it is disposed at a side of the separating insulated layer away from the base substrate to cover the output path of the light emitted by the second and third light emitting layers. Furthermore, the first light emitting layer and the second and third light emitting layers are respectively disposed on two sides of the separating insulated layer, and thus no mixing with each other will occur. Therefore, there is no strict requirement on the boundary of the first light emitting layer.

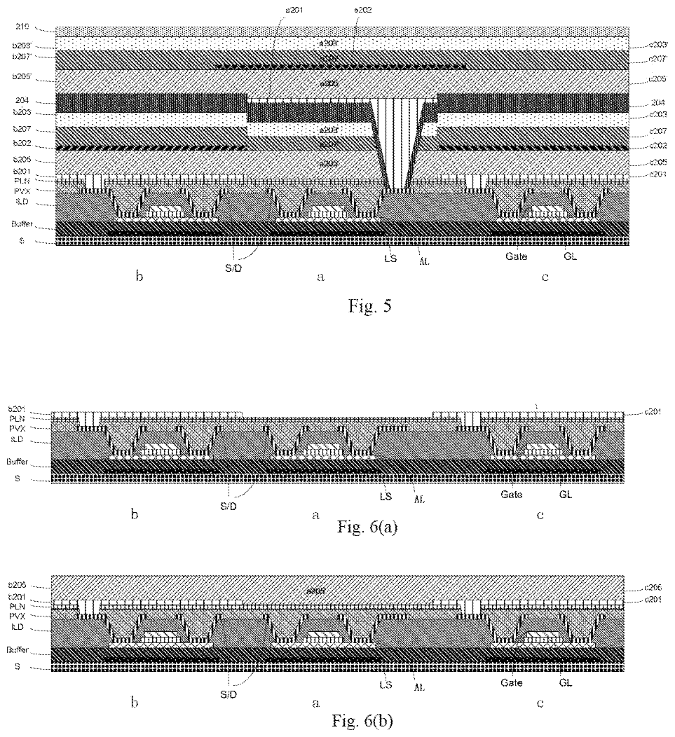

FIG. 5 schematically shows an exemplary film layer structure of another embodiment of the present disclosure. FIG. 5 differs from FIG. 1 in that the blue light emitting layer a202 extends into the second and third sub-pixel regions. Because the B EML is transparent to red and green light emitted, such extension will not adversely influence the light emitted by the second and third sub-pixels. Because the requirement on the boundary accuracy of the B EML is relatively low, a mask with a relatively low accuracy may be used, thereby saving the cost.

In an embodiment, the first light emitting layer may even extend to cover the entire effective display area of the display panel. In this case, an open mask rather than a fine metal mask may be used for fabricating the first light emitting layer. The term “open mask” refers to a mask which only blocks the peripheral area but exposes the display area completely. The cost and the operation difficulty of the open mask are much lower than those of the FMM. In this case, although some amount of the first light emitting material is wasted, the process and fabrication equipment are simplified, and the fabrication cost of the mask itself is significantly reduced.

In the display panel of the present disclosure, the interference between the sub-pixels due to the common functional layer is avoided by spatially designing the sub-pixel structure in a direction perpendicular to the base substrate. This may in turn omit the sub-pixel defining layer, achieving a high resolution display panel. It should be noted that the technical features of various embodiments above may be combined with each other and extended, as long as it is in line with the principle of the present disclosure.

The present disclosure also provides a method for manufacturing a display panel. The method comprises steps of: providing a base substrate; forming a second sub-pixel and a third sub-pixel at a side of the base substrate; forming a separating insulated layer at a side of the second sub-pixel and third sub-pixel away from the base substrate; and forming a first sub-pixel at a side of the separating insulated layer away from the base substrate. The manufacture method of the present disclosure comprises a step of forming the separating insulated layer. The manufacture method of the present disclosure may be used for manufacturing the display panel as described above.

In an embodiment, the step of forming a second sub-pixel and a third sub-pixel at a side of the base substrate comprises:

forming a second anode and a third anode respectively at one side of the base substrate, the second anode and the third anode being electrically connected to, for example, a TFT in the base substrate:

forming a hole injection layer and a hole transport layer sequentially at a side of the second anode and the third anode away from the base substrate and said one side of the base substrate:

forming a second light emitting layer and a third light emitting layer respectively at a side of the hole transport layer away from the base substrate; and

forming an electron transport layer, an electron injection layer, and a cathode layer sequentially at a side of the second light emitting layer, the third light emitting layer and the hole transport layer away from the base substrate, thereby forming the second and third sub-pixels.

The step of forming a separating insulated layer at a side of the second sub-pixel and the third sub-pixel away from the base substrate comprises:

forming a through hole penetrating the cathode layer, the electron injection layer, the electron transport layer, the hole transport layer and the hole injection layer sequentially and arriving at the base substrate; and

forming the separating insulated layer at a side of the cathode away from the base substrate and on an inner wall of the through hole.

The step of forming a first sub-pixel at a side of the separating insulated layer away from the base substrate comprises:

forming a first anode electrically connected to the base substrate via the through hole;

forming a hole injection layer and a hole transport layer sequentially at a side of the first anode and the separating insulated layer away from the base substrate;

forming a first light emitting layer at a side of the hole transport layer away from the base substrate; and

forming an electron transport layer, an electron injection layer and a cathode sequentially at a side of the first light emitting layer away from the base substrate.

In other words, the display panel of the present disclosure is formed by forming the film layers layer by layer. All the steps may be conventional steps in related art.

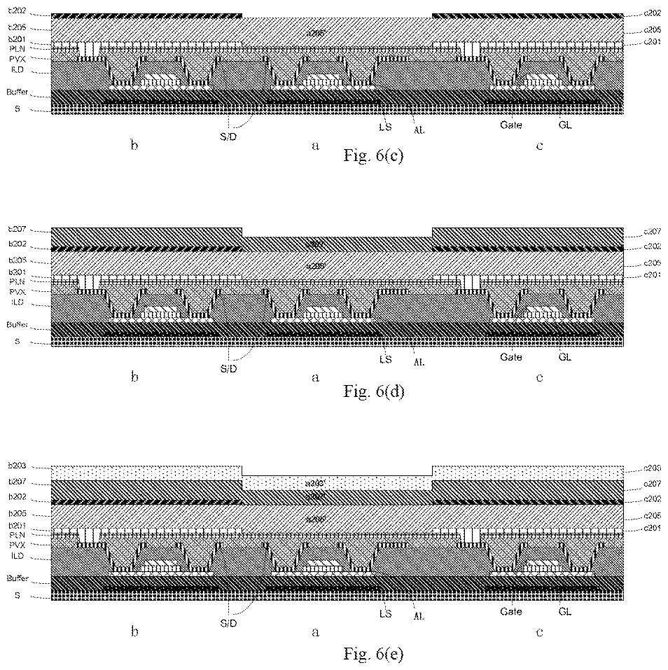

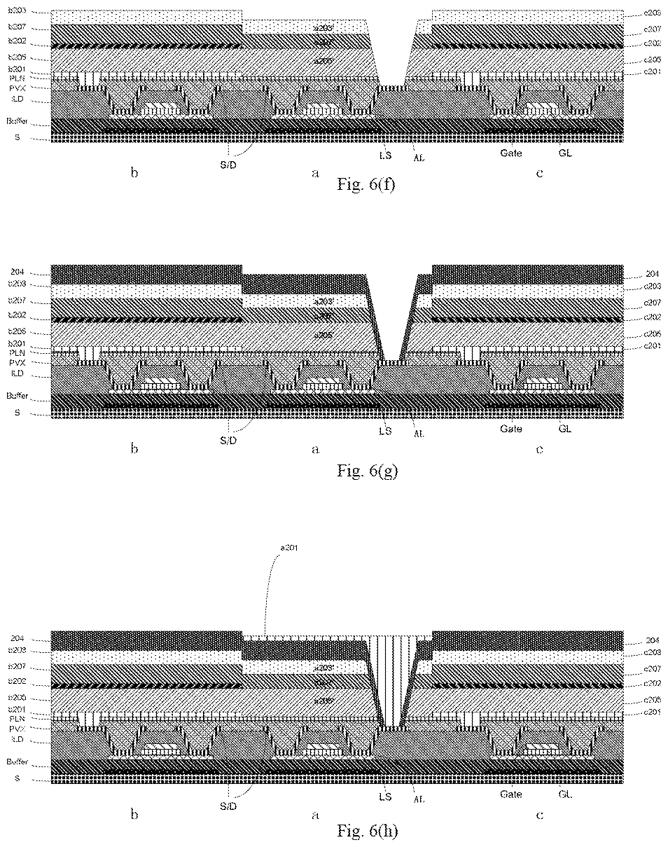

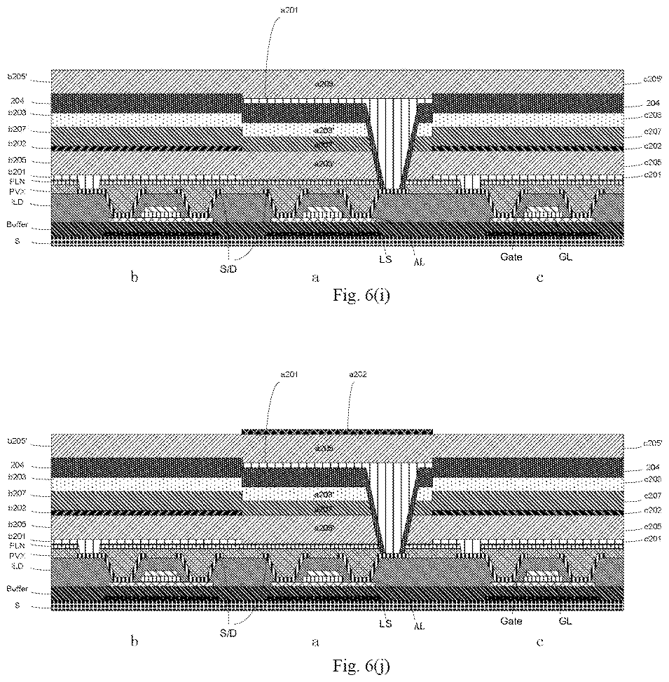

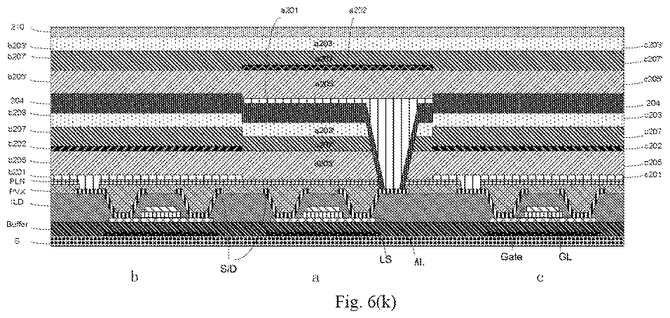

FIGS. 6(a)-(k) schematically shows the manufacture steps of an embodiment of the present disclosure.

Generally, in the manufacture of a high resolution display panel, it is necessary to use the fine metal mask (FMM) for fabricating the light emitting layer of each sub-pixel. However, as described above, because the first light emitting layer and the second and third light emitting layers are respectively disposed on two sides of the separating insulated layer, no mixing will occur, and the first light emitting layer will no adversely influence the luminescence of the second and third sub-pixels even if it extends into the second and third sub-pixel regions. Therefore, as described above, it is possible to not use a fine metal mask, but only use an open mask with a relatively low accuracy to form the first light emitting layer in the entire display area. Furthermore, because the second and third light emitting layers are disposed the same level in the film layer structure, it is still necessary to maintain a distance between their boundaries to avoid mixing. For example, between the red sub-pixel and the green sub-pixel adjacent in a diagonal direction as shown in FIG. 3, the red light emitting layer and the green light emitting layer should not be mixed. Therefore, the second and third light emitting layers are preferably formed by using a FMM. A suitable FMM may be selected according to the accuracy requirement for the sub-pixel. As described above, when the first anode is opaque, the second and third light emitting layer may be formed by using a FMM with a relatively large opening.

In an embodiment, in the first sub-pixel, the second sub-pixel and the third sub-pixel of one pixel unit, when forming each film layer other than the anode and the light emitting layer in one sub-pixel, the film layer is formed in the same layer in the other two sub-pixels. For example, the film layer may be a hole/electron injection/transport/blocking layer, an encapsulation layer, or the like. Each common layer is formed in the same layer. i.e., formed in the same overlaying process. For example, after forming the second and third anodes, while forming the hole injection layer of the first sub-pixel as described before, such a film layer may be formed in the same layer at a side of the separating insulated layer away from the base substrate at the positions of the second sub-pixel and the third sub-pixel in the same overlaying process. The overlaying process may be usual processes such as coating, depositing, or the like, and may be selected according to particular common layer.

In an embodiment, as described before, a first sub-pixel through hole is formed before depositing the separating insulated layer. For example, laser may be used to form an inverse conical hole in the film layers between the separating insulated layer and the TFT at the first sub-pixel. As compared to dry etching or wet etching, laser perforating may rapidly penetrate many materials, thereby creating a passage to the TFT in one process. Furthermore, the inverse conical shape of the through hole facilitates depositing an insulating layer on the inclined inner wall. While depositing the separating insulated layer, the material for the separating insulated layer is deposited on the wall of the inverse conical hole to form the first sub-pixel through hole.

FIGS. 6(a)-(k) show an embodiment of the present disclosure, wherein the display panel is formed layer by layer.

As shown in FIG. 6(a), a TFT array substrate is firstly provided, wherein each pixel unit comprises three TFTs. A light shielding layer (LS) and a buffer layer (Buffer) are formed on a base substrate (S). The TFT is formed on the buffer layer. Each TFT comprises source/drain electrodes (S/D), a gate electrode (Gate), a gate insulation layer (IG), an active layer (AL), and an interlayer dielectric layer (IDL). A passivation layer (PVX) and a planarization layer (PLN) are further provided on the top of the TFT array substrate. Such an array substrate may be provided by any suitable process well known in related art.

Then, through holes penetrating the passivation layer and the planarization layer are formed in the regions of the second sub-pixel and the third sub-pixel. Then a second anode b201 and a third anode c201 are formed, and are electrically connected to source/drain electrodes of a TFT via a through hole respectively.

Then, as shown in FIG. 6(b), hole injection/transport layers are formed. They serve as functional layers b205 and c205 in the second and third sub-pixel regions, but serve as a virtual layer a205′ in the first sub-pixel region.

Then, as shown in FIG. 6(c), a second light emitting layer b202 and a third light emitting layer c202 are formed respectively. No light emitting layer is formed in the first sub-pixel region.

Then, as shown in FIG. 6(d), electron transport/injection layers are further formed. They serve as functional layers b207 and c207 in the second and third sub-pixel regions, but serve as a virtual layer a207′ in the first sub-pixel region.

Then, as shown in FIG. 6(e), an electrode layer is further overlaid. It serves as cathode layers b203 and c203 in the second and third sub-pixel regions, but serves as a virtual electrode a203′ in the first sub-pixel region.

Then, as shown in FIG. 6(f), an inverse conical hole penetrating all film layers till the source/drain electrodes of the TFT is formed in the first sub-pixel region.

Then, as shown in FIG. 6(g), a separating insulated layer 204 is formed. It covers the electrode layer, and covers the inner wall of the inverse conical hole. The TFT source/drain electrode at the bottom of the inverse conical hole remains exposed.

Then, as shown in FIG. 6(h), a first anode a201 is formed, and is electrically connected to the TFT source/drain electrodes via the inverse conical hole.

Then, as shown in FIG. 6(i), hole injection/transport layers are formed. They serve as virtual layers b205′ and c205′ in the second and third sub-pixel regions, but serve as a functional layer a205 in the first sub-pixel region.

Then, as shown in FIG. 6(j), a first light emitting layer a202 is formed. No light emitting layer is formed in the second and third sub-pixel regions.

Finally, as shown in FIG. 6(k), electron transport/injection layers, a cathode layer and an encapsulation layer are further formed, thereby obtaining a display panel.

Particular procedures in the above steps may be completed by any suitable process, which is not particularly limited in the present disclosure. Nevertheless, an open mask may be used in the step as shown in FIG. 6(j) to form the first light emitting layer a202 with a relatively low accuracy, which may extend into the regions of the second sub-pixel and the third sub-pixel. A fine metal mask may be used in the step as shown in FIG. 6(c) to ensure that no mixing will occur between the second light emitting layer b202 and the third light emitting layer c202 at the same level.

As schematically shown in the figure, the pixel unit of the display panel of the present disclosure comprises a first sub-pixel, a second sub-pixel, and a third sub-pixel. The display panel comprises a separating insulated layer, and the second and third sub-pixels and the first sub-pixel are disposed on two sides of the separating insulated layer respectively. The interference between the sub-pixels due to the common functional layer may be avoided by spatially designing the sub-pixel structure in a direction perpendicular to the base substrate. This may in turn omit the sub-pixel defining layer, achieving a high resolution display panel.

Obviously, modifications and variations on the embodiments of the present disclosure may be made by those skilled in the art without departing from the spirit and scope of the present application. As such, if these modifications and variations fall within the scopes of the claims of the present application or equivalents thereof, the present application is intended to encompass these modifications and variations.

1. A display panel comprising:
a base substrate comprising a display area and a peripheral area surrounding the display area;
first sub-pixels, second sub-pixels and third sub-pixels disposed in the display area; and
a separating insulated layer disposed at a side of the base substrate, an orthographic projection of the separating insulated layer on the base substrate at least covering the display area,
wherein the first sub-pixels are disposed at a side of the separating insulated layer away from the base substrate, and the second sub-pixels and the third sub-pixels are disposed between the separating insulated layer and the base substrate.

2. The display panel according to claim 1, wherein,
the first sub-pixel comprises a first anode, a first light emitting layer and a first cathode stacked at the side of the separating insulated layer away from the base substrate.

3. The display panel according to claim 1, wherein the second sub-pixel comprises a second anode, a second light emitting layer and a second cathode stacked between the base substrate and the separating insulated layer; and
the third sub-pixel comprises a third anode, a third light emitting layer and a third cathode stacked between the base substrate and the separating insulated layer.

4. The display panel according to claim 3, wherein the second anode and the third anode are disposed in the same layer, and the second cathode and the third cathode are disposed in the same layer.

5. The display panel according to claim 1, wherein the first sub-pixels are spaced apart from each other, and an orthographic projection of the first sub-pixel on the base substrate is between an orthographic projection of the second sub-pixel on the base substrate and an orthographic projection of the third sub-pixel on the base substrate.

6. The display panel according to claim 5, wherein an orthographic projection of the first sub-pixel on the base substrate is at least partially overlapped with an orthographic projection of the second sub-pixel on the base substrate and/or an orthographic projection of the third sub-pixel on the base substrate.

7. The display panel according to claim 5, wherein an orthographic projection of the second sub-pixel on the base substrate and an orthographic projection of the third sub-pixel on the base substrate are not overlapped with each other.

8. The display panel according to claim 1, wherein the first sub-pixels are blue sub-pixels, the second sub-pixels are green sub-pixels, and the third sub-pixels are red sub-pixels.

9. The display panel according to claim 1, wherein the display panel further comprises:
a buffer layer on the base substrate;
a thin film transistor layer at a side of the buffer layer away from the base substrate;
a passivation layer at a side of the thin film transistor layer away from the base substrate; and
a planarization layer at a side of the passivation layer away from the base substrate and between the base substrate and the second and third sub-pixels,
wherein the first sub-pixels, the second sub-pixels and the third sub-pixels are electrically connected to the thin film transistor layer via through holes penetrating the passivation layer and the planarization layer.

10. The display panel according to claim 1, wherein the display panel further comprises an encapsulation layer at a side of the first sub-pixels away from the base substrate, wherein an orthographic projection of the encapsulation layer on the base substrate at least covers the display area.

11. A method for manufacturing the display panel according to claim 1, comprising:
providing a base substrate;
forming a second sub-pixel and a third sub-pixel at a side of the base substrate;
forming a separating insulated layer at a side of the second sub-pixel and the third sub-pixel away from the base substrate; and
forming a first sub-pixel at a side of the separating insulated layer away from the base substrate.

12. The method according to claim 11, wherein the second sub-pixel and the third sub-pixel are formed by using a fine metal mask, and the first sub-pixel is formed by using an open mask.

13. A display device comprising the display panel according to claim 1.
